(19) United States
(12) Patent Application Publication
(10) Pub. No.: US 2022/0264805 A1
(43) Pub. Date: Aug. 25, 2022

(54) METHOD OF AND BUILDING FOR GROWING PLANTS

(71) Applicant: Clearvue Technologies Ltd, West Perth, Western Australia (AU)

(72) Inventors: Mikhail Vasiliev, West Perth, Western Australia (AU); Jacqualine Anne Thomas, West Perth, Western Australia (AU)

(21) Appl. No.: 17/628,612

(22) PCT Filed: Jul. 20, 2020
(86) PCT No.: PCT/AU2020/050746

§ 371 Date: Jan. 20, 2022

(30) Foreign Application Priority Data
Jul. 24, 2019 (AU) 2019902611

(51) Int. Cl. A01G 7/04; A01G 9/22; A01G 9/14; G02B 5/28

(52) U.S. Cl. CPC A01G 7/045; A01G 9/22; A01G 9/1438; G02B 5/285

(57) ABSTRACT

A method of growing plants comprising determining preferential light wavelengths for promoting growth of a plant. The method further comprises constructing one or more light filtering panels arranged to filter natural sunlight or artificial light to produce filtered light comprising the preferential wavelengths. In addition, the method comprises locating one or more plants in a structure constructed at least in part from one or more of the panels. The method also comprises illuminating the structure from outside with natural sunlight or artificial light to pass through the one or more panels and produce the filtered light wherein the filtered light is directed to radiate the plants.

### TECHNICAL FIELD

This document discloses a method of and a building for growing plants, typically, but not exclusively, for food for human or animal consumption.

### BACKGROUND ART

Food and its potential scarcity has been a topic of discussion for many years around the world. One of the main concerns for growers is ensuring that produce grows at a quick and optimum rate whilst maintaining nutritional quality.

To this end some researchers have considered using artificial lighting either to extend the growth time per day or to provide selected wavelengths to enhance or otherwise modify plant growth. In relation to the latter, programmable LED systems are commercially available enabling the emission of selected wavelengths to promote plant growth.

Various glasshouse structures have also been proposed which incorporate photovoltaic (PV) cells or modules. However, the PV cells are opaque. Therefore, part of the light incident on the glasshouse is transmitted through the glass and absorbed by the plants while another portion is absorbed by the PV cells to generate electricity. The PV cells accordingly shade the underlying plants from the sunlight. To provide uniform growing of the plants within the greenhouse, there is a need for the plants to be moved or rotated.

Another type of greenhouse has been proposed which uses Fresnel lens embedded into the greenhouse surface to focus direct light onto PV modules inside the greenhouse. This still creates a shading problem although the effects may be less severe than when the PV modules are on the greenhouse surface.

Is has also been proposed to use semi-transparent PV modules on the greenhouse surface which allow some light to pass through for plant growth with the non-transmitted light is used for electricity generation.

### SUMMARY OF THE DISCLOSURE

In broad and general terms, the idea or concept behind the present disclosure is to modify the illumination spectrum of light transmitted through a greenhouse surface to improve plant yield. It is also desired to strive for this with a view to maximise energy efficiency and savings. To this end some embodiments of the disclosed method envisage determining preferential wavelengths or light spectrum for the growth of a particular type of plant and constructing a greenhouse with panels that are tuned to filter natural sunlight or artificial light to produce the preferential wavelengths or spectrum. Some embodiments further envisage using complementary wavelengths or spectrum to those transmitted, for the generation of electricity. This electricity may be used to power artificial light sources that facilitate the generation of the preferred wavelengths/spectrum for radiating the plants and thereby extend the hours per day for growth of the plants.

In one aspect there is disclosed a method of growing plants comprising:

determining preferential light wavelengths for promoting growth of a plant;

constructing one or more light filtering panels arranged to filter natural sunlight or artificial light to produce filtered light comprising the preferential wavelengths;

locating one or more plants in a structure constructed at least in part from one or more of the panels;

illuminating the structure from outside with natural sunlight or artificial light to pass through the one or more panels and produce the filtered light wherein the filtered light is directed to radiate the plants.

In one embodiment constructing one or more light filtering panels comprises forming or locating a filter on a light transmissive substrate wherein the filter is arranged to filter natural sunlight or artificial light to produce the filtered light.

In one embodiment the method comprises constructing the filter using one or more inorganic materials.

In one embodiment constructing the filter comprises constructing the filter with 2N+1 layers of material where N is an integer ≥1 wherein the filter comprises a central layer and N layers on each side of the central layer.

In one embodiment 2≤N≤8.

In one embodiment the method comprises constructing the filter with at least one layer made from or comprising silver.

In one embodiment the method comprises constructing the filter with at least one layer made from or comprising Al₂O₃.

In one embodiment the method comprises constructing the filter with at least one layer made from or comprising ZnS.

In one embodiment the method comprises forming the layers in respective pairs of layers wherein each pair of layers is constituted by a respective layer one on each side of the central layer and spaced by a same number of layers from the central layer, and wherein layers in each layer pair (a) have substantially the same thickness; or (b) are made of the same materials; or (c) have substantially the same thickness and are made of the same materials.

In one embodiment the method comprises arranging the panels to generate electricity using the natural sunlight or artificial light illuminating the one or more panels.

In one embodiment the method comprises using a portion of the light spectrum complementary to the filtered light for generating the electricity.

In one embodiment the method comprises powering one or more light sources using the generated electricity to facilitate production of the preferential wavelengths for radiating the plants when natural sunlight is at an intensity below a threshold level.

In one embodiment the one or more light sources are located outside of the structure and the preferential wavelengths are produced by light from the one or more light sources passing through the one or more light filtering panels.

In one embodiment the one or more light sources are located inside of the structure and are arranged to generate light comprising the preferential wavelengths.

In one embodiment the method comprises directing the portion of the natural sunlight or artificial light illuminating the one or more panels to edges of the panels.

In one embodiment the method comprises location photovoltaic cells at locations along the edges to generate electricity from the portion of the light.

In a second aspect there is disclosed a greenhouse arrangement for growing plants comprising:

a plurality of light filtering panels arranged to filter natural sunlight or artificial light to produce filtered light comprising wavelengths preferential for growth of a species of plant;

each panel including a light transmissive substrate substantially transparent to natural sunlight or artificial light and a filter formed or supported on the substrate and arranged to filter the natural sunlight or artificial light to produce the filtered light; and

wherein at least some of the panels are provided with one or more photovoltaic cells along edges thereof and the panels are arranged to direct a portion of the natural sunlight or artificial light to one or more of the photovoltaic cells.

In one embodiment the filter comprises 2N+1 layers of material where N is an integer ≥1 wherein the filter comprises a central layer and N layers on each side of the central layer.

In one embodiment 2≤N≤8.

In one embodiment the thin film filter has at least one layer made from or comprising silver.

In one embodiment the thin film filter has at least one layer made from or comprising Al₂O₃.

In one embodiment the thin film filter has at least one layer made from or comprising ZnS.

In one embodiment the thin film filter comprises respective pairs of layers, each pair constituted by a respective layer one on each side of the central layer and spaced by a same number of layers from the central layer, and wherein layers in each layer pair: (a) have substantially the same thickness; or (b) are made of the same materials; or (c) have substantially the same thickness and are made of the same materials.

In one embodiment the greenhouse comprises one or more light sources powered by electricity generated by the PV cells, the light sources arranged to facilitate production of light having the preferential wavelengths for radiating the plants when natural sunlight is at an intensity below a threshold level.

In one embodiment the one or more light sources are located on a side of the panels opposite the plants and are arranged to produce either artificial sunlight or light having the preferential wavelengths.

In one embodiment the one or more light sources are located on a same side of the panels as the plants and are arranged to generate light comprising the preferential wavelengths.

In a third aspect there is disclosed a greenhouse arrangement for growing plants comprising:

a plurality of light filtering panels arranged to filter natural sunlight or artificial light to produce filtered light comprising wavelengths preferential for growth of a species of plant;

each panel including a light transmissive substrate substantially transparent to natural sunlight or artificial light and a thin film filter formed or supported on the substrate and arranged to filter the natural sunlight or artificial light to produce the filtered light; and

wherein the thin film filter comprises 2N+1 layers where N is an integer ≥1 and the filter comprises a central layer and N layers on each side of the central layer.

In a fourth aspect there is disclosed panel for a greenhouse comprising:

a light transmissive substrate substantially transparent to natural sunlight or artificial light and a filter formed or supported on the substrate and arranged to filter the natural sunlight or artificial light to produce filtered light comprising wavelengths preferential for growing a species of plant;

one or more PV cells along edges of the substrate; and

wherein the filter or another medium is arranged to direct a portion of the natural sunlight or artificial light to one or more of the PV cells.

In a fifth aspect there is disclosed panel for a building comprising:

a light transmissive substrate substantially transparent to natural sunlight or artificial light and a filter formed or supported on the substrate and arranged to filter the natural sunlight or artificial light to produce filtered light comprising selected wavelengths; and

wherein the filter comprises 2N+1 layers of material where N is an integer ≥1 and the filter comprises a central layer and N layers on each side of the central layer.

In a sixth aspect there is disclosed panel for a building comprising:

a light transmissive substrate substantially transparent to natural sunlight or artificial light and a filter formed or supported on the substrate and arranged to filter the natural sunlight or artificial light to produce filtered light comprising selected wavelengths;

one or more PV cells along edges of the substrate; and

wherein the filter or another medium is arranged to direct a portion of the natural sunlight or artificial light to one or more of the PV cells.

### BRIEF DESCRIPTION OF THE DRAWINGS

Notwithstanding any other forms which may fall within the scope of the system and method as set forth in the Summary, specific embodiments will now be described by way of example only with reference to the accompanying drawings in which:

FIG. 1 illustrates a proposed matrix of pots for growing lettuce in a growth tent; and

FIG. 2 is a simulated plot of wavelength transmission acquired from using the proprietary software of Opti-Layer Pro for a nine layer filter made from Al₂O₃, ZnS and Ag, together with the measured plot from an actual filter.

### DESCRIPTION OF SPECIFIC EMBODIMENTS

For ease of reference the following embodiments are described in relation to the growth of Lactuca sativa, L hereinafter referred to by its common name “lettuce”. However, the described embodiments apply to any plant.

Lettuce plants are quantitative long-day plants at high temperature and day-neutral plants at low temperature. A long-day plant is one in which the length of the day is longer than the length of night that the plant detects. A day-neutral plant is one in which the length of day is not a factor in the flowering of the plant. The quantitative term refers to the dependence on a factor such as temperature for flowering.

Embodiments of the proposed method and corresponding greenhouse involve determining or otherwise identifying the wavelengths or spectral components from natural sunlight required for enhanced or optimum growth of a particular plant.

This can be achieved by literature research or by experimentation.

An example of a setup for experimentally determining preferential wavelengths for the growth of lettuce is described below.

This experiment utilised three growth tents, one used as a control tent and two experimental tents. Each tent has identical length, width and height dimensions of 1.5 m×1.5 m×2 m. Tents of this size can fit at least 30 plants in 100 mm pots in the base of each grow tent. The tents also have a reflective coating on their entire inside surface to reflect the LED light within each tent. This minimizes shading of plants.

Shading is a concern, as plants will ‘bolt’ their growth and develop sooner than desired, with biomass being less than preferable if they are shaded too much from the light. Similarly, too much light could have the same consequence.

A tunable light source was provided for each tent. In this example, the light source chosen was the Heliospectra™ LX602C LED tunable light source supplied by Heliospectra of Goteborg, Sweden (see https://www.heliospectra.com/). This source enables the wavelength of light output by the LEDs to be tuned to specific wavelengths by an internet connection to the Internet Protocol (IP) address of the specific Heliospectra™ LED light being tuned. The interface can be used to tune the wavelength of light output by the LEDs between 450 nm (blue), 660 nm (red), 735 nm (far red) and 5700K (white).

More than one wavelength may be set to be output at a specific time. The Heliospectra™ LEDs also provide the ability to control the output power, which in turn controls the intensity of the light being output by the LEDs. The ‘intensity’ is variable between 0 and 1000, being equivalent to 0% to 100% of power being output by the LED light.

The light sources were suspended from inside 2 m high tents at a height of 1.53 m. This provided each of the 30 test plants with optimum amounts of light with no or minimal shading. Depending on the light source used it may be necessary for it to be calibrated at an optimum intensity to provide optimum growth. In order to set the intensity of the Heliospectra™ LED lights, a hand-held laser power meter was used for intensity calibration. This enables calculation of the Energy density (W/m²) of the system at a particular height from the ground that the measurement was taken.

The light source in the first (control) tent was arranged to provide light across the visible spectrum at 5700K temperature. (The Heliospectra™ LED lights also enable, if required, the red and blue LED lights to be turned on to ensure as much of the ‘white’ spectrum is being radiated on the plants).

The light source in the second tent was arranged to provide only blue LED light (450 nm) and red LED light (660 nm). The light source in the third tent was arranged to provide red LED light (660 nm), far red LED light (735 nm) and blue LED light (450 nm).

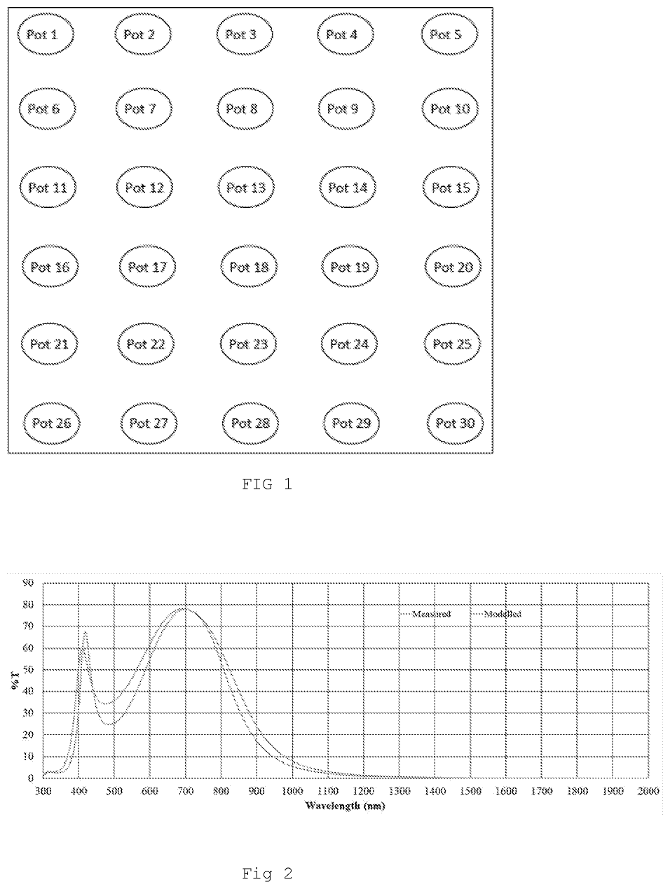

The lettuce plants were positioned within each tent initially in the same matrix patterns as shown in FIG. 1 and rotated weekly to avoid positional lighting problems.

Across the three tents, 90 baby butter head lettuce seedlings were sown individually in high quality seed and cutting potting mix in 13 mm pots. An additional sample of 5 seedlings were culled, dried, weighed and averaged to obtain a zero biomass starting point. The position of the plants within each tent was randomised every 7-8 days throughout the duration of a thirty nine day experiment. 50 mL of water was supplied by hand every day to each individual plant within each tent. Every 14 days, 50 mL of diluted liquid nutrient was supplied to each plant, without any additional water at that time.

The parameters measured in the experiment to determine preferred growth wavelengths included the wet weight (g/plant), dry weight (g/plant) and biomass (g) of each plant. The photosynthetically active radiation (PAR) was measured via correlation to the power density for each light treatment and the photosynthetic photon flux (PPF) density (μmolm⁻² s⁻¹) was calculated. The result of these calculations are set out in Table 1 below.

TABLE 1
The normalized ratio of blue to red LED light and
red to far-red LED light using the calculated PPF.

| | Photosynthetic | Blue to Red | Red to Far- |
|---|---|---|---|
| Grow Tent | Photon Flux | ratio | Red ratio |
| 1 - White, 1000 | ~101 μmolm−2s−1 | N/A | N/A |
| ‘intensity’ | (3 s.f.) | | |
| 2 - Blue, 1000 | ~61.9 μmolm−2s−1 | 1:6.6 | N/A |
| ‘intensity’; Red, | (3 s.f.) | | |
| 3 - Blue, 1000 | ~70.6 μmolm−2s−1 | 1:6.6 | 1:0.16 |
| ‘intensity’; Red, | (3 s.f.) | | |

The first (White) control grow tent had a greater PPF than the third (Blue, Red, Far Red) grow tent, yet the first (White) grow tent had the least biomass, and the third grow tent (Blue, Red, Far Red) had the greatest biomass. The average fresh leaf weight, dry leaf weight and biomass of the plants are shown in Table 2.

TABLE 2
The average fresh weight (FW), average dry weight
(DW) and average biomass over the 90-plant sample.

| | | Leaf | | |
|---|---|---|---|---|
| | | Average | Average | Average |
| | LED | FW | DW | Biomass |
| Day | Radiation | (g/plant) | (g/plant) | (g/plant) |
| 0 - Zero | N/A | 1.68 | 0.07 | 0.07 |
| 39 | White | 83.45 | 4.91 | 4.84 |
| | Blue + Red | 84.55 | 5.22 | 5.15 |
| | Blue + Red + | 84.23 | 5.62 | 5.55 |
| | Far Red visible | | | |

The results indicate that the light condition of Blue+Red+Far Red visible LED light (448 nm blue; red 650 nm-678 nm, and far red visible, 714 nm-758 nm respectively) provided the highest average dry weight and the highest average biomass, and the second highest average fresh weight. The highest wet weight was produced under the blue and red visible LED light radiation. The white LED light radiation which was used as the control, produced the lowest average fresh weight, the lowest average dry weight and the lowest average biomass.

The biomass results indicate that on comparison with the white (W) light radiation, the biomass in the Blue+Red+Far Red light radiation was ˜14.7% (3 s.f.) higher than the biomass in the W light radiation. Additionally, the biomass in the Blue+Red light radiation in comparison to the W light radiation, was ˜6.41% (3 s.f.) higher than the W light radiation. The light in the W light radiation was broader and received more PPF than the discrete radiation in the Blue+Red, and the Blue+Red+Far Red light radiations, therefore it would be presumed that the W control tent would have the greatest biomass. The results contradict this prediction.

From these experimental results it was considered that wavelength profile for preferential or at least enhanced growth of lettuce may have a narrow band central wavelength of 448 nm and the larger wavelength band of 666 nm-736 nm. All other wavelengths, that is, green (˜500-600 nm) visible, ultraviolet (UV ˜10 nm-˜400 nm) and infrared (IR ˜780 nm-1000 μm) are removed or attenuated.

From this experiment it was considered that, for lettuce, it may be appropriate to construct a light filtering panel for use in a greenhouse that attenuates wavelengths from 300 nm to 400 nm, provide maximum transmission (allows the visible light to pass through) at wavelengths of 401-500 nm (blue), suppress wavelength from 501 nm to 600 nm (green and yellow), and provide maximum transmission of wavelengths 601 nm to 750 nm (red and far red).

In this, but not necessarily every, embodiment a filter was designed having 2N+1 layers where N is an integer ≥1. In such an embodiment the filter may be constructed with a central layout and N layers on either side of the central layer. The layers on either side of the central layer may be formed as respective pairs. The layers in each pair are spaced by the same number of layers from the central layer. The filter can be formed or constructed so that the layers in each pair (a) have substantially the same thickness; or (b) are made of the same materials; or (c) have substantially the same thickness and are made of the same materials.

A filter that could be formed or supported on a substrate to form a light filtering panel filter, may be fabricated using three common optical materials: Al₂O₃, ZnS and Ag. Known techniques for producing the filter include electron beam evaporation and sputtering.

A nine layer filter made from Al₂O₃, ZnS and Ag was simulated via the software program Opti-Layer Pro, then constructed using the above materials. FIG. 2 shows the transmission characteristics of the simulated filter and actual constructed multi-layer filter. FIG. 2 shows that the actual filter has maximum transmission peaks around 420 nm and 680 nm.

Table 3 below describes the construction of a nine-layer filter made from Al₂O₃, ZnS and Ag which produced the measured data shown in FIG. 2. The central layer of the filter is layer number 5. The filter is structurally and optically balanced with the remaining eight layers formed symmetrically, in terms of thickness and material composition, about the central layer. The filter was constructed on a lmm thick substrate made of Corning Eagle™ glass.

TABLE 3
Design of nine-layer filter for enhanced lettuce growth.

| Layer | Physical layer | |
|---|---|---|
| Number | thickness (nm) | Material |
| 1 | 35 | Al₂O₃ |
| 2 | 40 | ZnS |
| 3 | 21 | Ag |
| 4 | 40 | ZnS |
| 5 | 50 | Al₂O₃ |
| (central layer) | | |
| 6 | 40 | ZnS |
| 7 | 21 | Ag |
| 8 | 40 | ZnS |
| 9 | 35 | Al₂O₃ |

The filter may have any number of layers and can be made from various materials not only those mentioned above depending on the required wavelength profile or spectrum. For example, while N could range between 2≤N≤8 to produce a filter of between 3 and 17 layers more layers may be used or incorporated in the filter. It is believed that using more than the nine layers in the above example will provide better correlation to the model of FIG. 2 in the green range of the visible spectrum.

Having now determined the wavelength characteristics for promoting or enhancing the growth of the plant, in this case lettuce, a structure such as a greenhouse may be constructed using panels having required light filtering characteristics. Where the greenhouse is illuminated by natural sunlight, and plants are located within the greenhouse, the plants will now receive the filtered sunlight comprising wavelengths which enhance or optimise growth.

In simplest form this may be manifested by forming filters of the type described above on substrates and then supporting those substrates on common structural greenhouse glass panels or forming such filters directly on structural glass that can be used in the construction of a greenhouse.

Embodiments of the disclosed filter may also be incorporated in light transmissive panels that incorporate photovoltaic cells for generating electricity. The cells may charge rechargeable batteries located either within the panels themselves or exterior to the panels. When photovoltaic cells are incorporated in such panels, wavelengths complementary to those of the filtered light may be directed to the photovoltaic cells to generate electricity. In turn this electricity may be used to power artificial light sources either inside or outside of the greenhouse to extend the growing hours available to the plants in comparison to the natural daylight hours.

When located outside of the greenhouse the artificial light sources may be arranged to produce either (a) artificial sunlight or (b) radiation matched to the transmission characteristics of the filter. In the case of (a), complementary portions of the artificial sunlight may be used to generate further electricity.

When the artificial light sources are located inside of the greenhouse they may be arranged to produce radiation of the same or similar wavelength profile or spectrum as the filtered light. Also, when located inside of the greenhouse, the light sources may be located or arranged in a way to minimise shading during daylight hours.

An example of a commercially available light transmissive panel that is well suited to this application is that produced by the present Applicant ClearVue Technologies Ltd (see http://www.clearvuepv.com/). More details of the panels can be found in the following patent specifications, the contents of which are incorporated herein by way of reference: PCT/AU2012/000778, PCT/AU2012/000787 and PCT/AU2014/000814. In broad terms these patent specifications describe a spectrally selective panel that may be used as a windowpane and that is largely transmissive for visible light but diverts a portion of incident light to side portions of the panel where it is absorbed by photovoltaic elements to generate electricity. The disclosed panels are integrated with a window frame, which carries both the panels and the photovoltaic elements solar cells.

Now that embodiments of the method, filter and greenhouse have been described it should be appreciated that the embodiments may take many other forms and extend to other applications outside of plant growth.

For example, embodiments of the disclosed filter used in the light filtering panels may have an even number of layers rather than the odd number of layers 2N+1 described above. The specific materials used in construction of the filter can be chosen from any known materials having the required wavelength transmission/attenuation properties to produce a desired wavelength profile or spectrum. Embodiments may also be applied to light transmissive panels for a building that may not necessarily be a greenhouse. For example, the panels may be applied to a building where it may be desirable to have sunlight filtered to produce a desired internal ambience. Also, the filter may be made from other materials or combinations of materials that produce the desired preferential wavelengths. In one example a suitable combination of materials may be: MgF₂, ZnS and Ag.

Any discussion of the background art throughout this specification should in no way be considered as an admission that such background art is prior art, nor that such background art is widely known or forms part of the common general knowledge in the field in Australia or worldwide.

In the claims which follow and in the preceding description, except where the context requires otherwise due to express language or necessary implication, the word “comprise” and variations such as “comprises” or “comprising” are used in an inclusive sense, i.e. to specify the presence of the stated features but not to preclude the presence or addition of further features of the embodiments as disclosed herein.

1-30. (anceled)

31. A method of growing plants comprising:
determining preferential light wavelengths for promoting growth of a plant;
constructing one or more light filtering panels arranged to filter natural sunlight or artificial light to produce filtered light comprising the preferential wavelengths;
locating one or more plants in a structure
constructed at least in part from one or more of the panels; and
illuminating the structure from outside with natural sunlight or artificial light to pass through the one or more panels and produce the filtered light wherein the filtered light is directed to radiate the plants.

32. The method according to claim 31 wherein constructing one or more light filtering panels comprises forming or locating a filter on a light transmissive substrate wherein the filter is arranged to filter natural sunlight or artificial light to produce the filtered light.

33. The method according to claim 32 comprising constructing the filter using one or more inorganic materials.

34. The method according to claim 32 wherein constructing the filter comprises constructing the filter with 2N+1 layers of material where N is an integer ≥1 wherein the filter comprises a central layer and N layers on each side of the central layer.

35. The method according to claim 32 comprising constructing the filter with at least one layer made from or comprising silver, Al₂O₃ or ZnS.

36. The method according to claim 34 comprising forming the layers in respective pairs of layers wherein each pair of layers is constituted by a respective layer one on each side of the central layer and spaced by a same number of layers from the central layer, and wherein layers in each layer pair (a) have substantially the same thickness; or (b) are made of the same materials; or (c) have substantially the same thickness and are made of the same materials.

37. The method according to claim 31 comprising arranging the panels to generate electricity using the natural sunlight or artificial light illuminating the one or more panels.

38. The method according to claim 37 comprising using a portion of the light spectrum complementary to the filtered light for generating the electricity.

39. The method according to claim 37 comprising powering one or more light sources using the generated electricity to facilitate production of the preferential wavelengths for radiating the plants when natural sunlight is at an intensity below a threshold level.

40. The method according to claim 37 comprising directing the portion of the natural sunlight or artificial light illuminating the one or more panels to edges of the panels.

41. The method according to claim 40 comprising location photovoltaic cells at locations along the edges to generate electricity from the portion of the light.

42. A greenhouse arrangement for growing plants comprising:
a plurality of light filtering panels arranged to filter natural sunlight or artificial light to produce filtered light comprising wavelengths preferential for growth of a species of plant, each panel including a light transmissive substrate substantially transparent to natural sunlight or artificial light and a filter formed or supported on the substrate and arranged to filter the natural sunlight or artificial light to produce the filtered light;
wherein at least some of the panels are provided with one or more PV cells along edges thereof and the panels are arranged to direct a portion of the natural sunlight or artificial light to one or more of the PV cells.

43. The greenhouse according to claim 42 wherein the filter comprises 2N+1 layers of material where N is an integer ≥1 wherein the filter comprises a central layer and N layers on each side of the central layer.

44. The greenhouse according to claim 42 wherein the thin film filter has at least one layer made from or comprising silver, Al₂O₃ or ZnS.

45. The greenhouse according to claim 42 wherein the thin film filter comprises respective pairs of layers, each pair constituted by a respective layer one on each side of the central layer and spaced by a same number of layers from the central layer, and wherein layers in each layer pair: (a) have substantially the same thickness; or (b) are made of the same materials; or (c) have substantially the same thickness and are made of the same materials.

46. The greenhouse according to claim 42 comprising one or more light sources powered by electricity generated by the PV cells, the light sources arranged to facilitate production of light having the preferential wavelengths for radiating the plants when natural sunlight is at an intensity below a threshold level.

47. A greenhouse arrangement for growing plants comprising:
a plurality of light filtering panels arranged to filter natural sunlight or artificial light to produce filtered light comprising wavelengths preferential for growth of a species of plant, each panel including a light transmissive substrate substantially transparent to natural sunlight or artificial light and a thin film filter formed or supported on the substrate and arranged to filter the natural sunlight or artificial light to produce the filtered light;
wherein the thin film filter comprises 2N+1 layers where N is an integer ≥1 and the filter comprises a central layer and N layers on each side of the central layer.

48. A panel for a greenhouse comprising:
a light transmissive substrate substantially transparent to natural sunlight or artificial light and a filter formed or supported on the substrate and arranged to filter the natural sunlight or artificial light to produce filtered light comprising wavelengths preferential for growing a species of plant; and
one or more PV cells along edges of the substrate;
wherein the filter or another medium is arranged to direct a portion of the natural sunlight or artificial light to one or more of the PV cells.

49. A panel for a building comprising:
a light transmissive substrate substantially transparent to natural sunlight or artificial light and a filter formed or supported on the substrate and arranged to filter the natural sunlight or artificial light to produce filtered light comprising selected wavelengths;
wherein the filter comprises 2N+1 layers of material where N is an integer ≥1 and the filter comprises a central layer and N layers on each side of the central layer.

50. A panel for a building comprising:
a light transmissive substrate substantially transparent to natural sunlight or artificial light and a filter formed or supported on the substrate and arranged to filter the natural sunlight or artificial light to produce filtered light comprising selected wavelengths;
one or more PV cells along edges of the substrate;
wherein the filter or another medium is arranged to direct a portion of the natural sunlight or artificial light to one or more of the PV cells.
